(19) United States
(12) Patent Application Publication
(10) Pub. No.: US 2009/0035536 A1
(43) Pub. Date: Feb. 5, 2009

(54) PROCESS FOR PRODUCING THIN-FILM DEVICE, AND DEVICES PRODUCED BY THE PROCESS

(75) Inventors: Atsushi Tanaka, Ashigarakami-gun (JP); Kohei Higashi, Ashigarakami-gun (JP); Kenichi Umeda, Ashigarakami-gun (JP); Hiroshi Sunagawa, Ashigarakami-gun (JP); Katsuhiro Kohda, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/181,897

(22) Filed: Jul. 29, 2008

(30) Foreign Application Priority Data
Jul. 30, 2007 (JP) 2007-197000

(51) Int. Cl. G03G 7/00; B05D 3/00

(52) U.S. Cl. 428/195.1; 427/554

(57) ABSTRACT

In a process for producing a thin-film device, a thermal-buffer layer is formed over a substrate which contains a resin material as a main component, and a light-cutting layer is formed over at least a region of the substrate over which a non-monocrystalline film to be annealed is not to be formed, where the light-cutting layer prevents damage from short-wavelength light to the substrate by reducing a proportion of the short-wavelength light which reaches the substrate. Thereafter, the non-monocrystalline film which is to be annealed is formed in a pattern over the substrate having the thermal-buffer layer, and an inorganic film is formed by irradiating the non-monocrystalline film with the short-wavelength light so as to anneal the non-monocrystalline film.

### BACKGROUND OF THE INVENTION

1. Field of the Invention

The present invention relates to a process for producing a thin-film device which has an inorganic crystalline film formed in a pattern over a low-thermal-resistance substrate such as a resin substrate. The present invention also relates to the thin-film device produced by the above process. The thin-film device can be used in, for example, a semiconductor device such as a thin-film transistor. The present invention further relates to an electro-optic device using the above thin-film device, and a thin-film sensor using the thin-film device.

2. Description of the Related Art

Currently, various flexible devices are receiving attention. The use of the flexible devices is widely spread, and the flexible devices include, for example, electronic paper, flexible displays, and the like.

The flexible devices have a structure having a thin film of a crystalline semiconductor or metal which is formed in a pattern over a flexible substrate such as a resin substrate. Since the flexible substrate has lower thermal resistivity than the inorganic substrate such as the glass substrate, the entire manufacturing process is required to be executed under the thermal-resistance-limit temperature of the flexible substrate. For example, the thermal-resistance-limit temperature of the resin substrate is normally 150 to 200° C., although the thermal-resistance-limit temperature depends on the material. Even the thermal-resistance-limit temperatures of the thermally resistant materials are approximately 300° C. at the highest.

In particular, the baking temperatures of most inorganic thin films which are to be formed over a substrate as above exceed the thermal-resistance-limit temperature. Therefore, many inorganic thin films cannot be baked by heating. Even in the case where a thin film is baked by laser annealing (which can bake the thin film without directly heating the substrate), it is necessary to take measures to protect the substrate from damage which can be caused by heat transferred from the baked thin film and laser light passing through the thin film and reaching the substrate.

Japanese Unexamined Patent Publication No. 9(1997)-116158 (hereinafter referred to as JP9-116158A) discloses a semiconductor device having a light-weight substrate, a semiconductor thin film, and a heat dissipation means. The heat dissipation means is arranged in a layer between the substrate and the semiconductor thin film, and can sufficiently prevent damage to the substrate which can be caused by heat generated when an energetic beam crystallizes the semiconductor thin film.

Japanese Unexamined Patent Publication No. 11(1999)-102867 (hereinafter referred to as JP11-102867A) discloses a technique for forming a semiconductor thin film by forming an amorphous semiconductor film over a resin substrate through a thermal-buffer layer which stops thermal conduction, and irradiating the amorphous semiconductor film with an energetic beam.

Japanese Unexamined Patent Publication No. 5(1993)-259494 (hereinafter referred to as JP5-259494A) discloses a technique for producing a flexible solar cell. The technique includes a step of crystallization by irradiation with laser light. In the step, in order to suppress damage from heat to a substrate, the substrate is maintained at the temperature of −100° C. to 0° C. during the crystallization.

Japanese Unexamined Patent Publication No. 2004-063924 (hereinafter referred to as JP2004-063924A) discloses a technique for laser annealing a thin film of amorphous silicon over a resin substrate with laser light having a wavelength in the range of 350 to 550 nm. JP2004-063924A reports that since the absorption of the laser light having such a wavelength in the resin substrate is relatively small, the thermal distortion of the substrate caused by the laser light which reaches the substrate can be suppressed when the wavelength of the laser light with which the thin film is irradiated is in the above range.

Currently, the direct imaging technique is receiving attention as a technique for manufacturing a thin-film device with ease at low cost. In the case where the direct imaging technique is used, a thin-film device is manufactured by applying a raw-material solution containing one or more constituent materials of a thin film to a surface of or over a substrate by use of a printing technique such as inkjet printing or screen printing so as to form a predetermined pattern, and thereafter baking the thin film by laser annealing or the like. In this case, the raw-material solution is not applied to the areas of the surface on or over the substrate on which the patterned thin film is not to be formed. Since no film which absorbs the laser light exists on the areas of the surface of or over the substrate on which the patterned thin film is not formed, the proportion of the laser light which reaches the regions of the substrate under the above areas of the surface while the thin film is baked by the laser annealing is very high, although the substrate has low thermal resistivity. In particular, many resin substrates exhibit low transmittance of light at the short wavelengths smaller than 350 nm. Therefore, it is highly probable that the resin substrate can be damaged by heat produced by the absorption of the laser light which reaches the resin substrate.

However, JP9-116158A, JP11-102867A, JP5-259494A, and JP2004-063924A do not disclose information on the patterned films which are to be annealed. The thin films considered in JP9-116158A, JP11-102867A, and JP5-259494A are constituted by materials which approximately completely absorb the laser light (as the energetic beam) with which the thin films are irradiated. Therefore, in JP9-116158A, JP11-102867A, and JP5-259494A, the damage to the substrate caused by absorption of the laser light which reaches the substrate is not considered, and only the heat conduction to the substrate is suppressed.

In the technique disclosed in JP2004-063924A, the amorphous silicon film is used as the film to be annealed. Since the amorphous silicon exhibits high absorptivity in the range of wavelengths of the laser light from 350 to 550 nm, the amorphous silicon film can be annealed by laser light having a wavelength in this range. However, in the case where the material constituting the film to be annealed does not exhibit sufficient absorptivity in the range from 350 to 550 nm, crystallization by laser annealing becomes difficult. Therefore, the material constituting the film to be annealed is limited. In addition, in the case where the substrate exhibits high absorptivity in the range from 350 to 550 nm, there is a possibility that the substrate can be damaged by the laser light, although the possibility depends on the wavelength and the amount of light which reaches the substrate.

### SUMMARY OF THE INVENTION

The present invention has been developed in view of the above circumstances.

The first object of the present invention is to provide a process for producing a thin-film device, which enables production of a thin-film device having a high-quality inorganic film by use of the direct imaging technique without damage to a resin substrate, and annealing of non-monocrystalline films formed of various materials. Although the high-quality inorganic film produced by the process according to the present invention preferably has satisfactory crystallinity, the high-quality inorganic film produced by the process according to the present invention is not limited to an inorganic crystalline film, and generally includes the inorganic films which can be obtained by annealing a film.

The second object of the present invention is to provide a thin-film device produced by the process achieving the first object.

The third object of the present invention is to provide an electro-optic device using the thin-film device achieving the second object.

The fourth object of the present invention is to provide a thin-film sensor using the thin-film device achieving the second object.

(I) In order to accomplish the first object, the first aspect of the present invention is provided. According to the first aspect of the present invention, there is provided a process for producing a thin-film device. The process comprises a step (A) of preparing a substrate which contains a resin material as a main component, a step (B) of forming a thermal-buffer layer over the substrate, a step (D) of forming in a pattern over the substrate having the thermal-buffer layer a non-monocrystalline film which is to be annealed, and a step (E) of forming an inorganic film by irradiating the non-monocrystalline film with short-wavelength light so as to anneal the non-monocrystalline film. In particular, the process according to the first aspect of the present invention is characterized in further comprising between the steps (B) and (D) a step (C) of forming a light-cutting layer over at least a region of the substrate over which the non-monocrystalline film to be annealed is not to be formed, where the light-cutting layer prevents damage from the short-wavelength light to the substrate by reducing the proportion of the short-wavelength light which reaches the substrate.

In this specification, the “main component” means a component the content of which is 90 weight percent or more, and the “short-wavelength light” means light having a wavelength smaller than 350 nm.

Preferably, the process according to the first aspect of the present invention may also have one or any possible combination of the following additional features (i) to (viii).

(i) The step (D) and the step (E) may be performed one or more times after the step (E) is first performed.

(ii) The process according to the first aspect of the present invention can be preferably applied to production of a thin-film device in which the inorganic film has crystallinity.

(iii) The light-cutting layer may be either a type which absorbs the short-wavelength light or a type which reflects the short-wavelength light.

(iv) The transmittance of the short-wavelength light through the light-cutting layer is required to be so low as to reduce the short-wavelength light to such a degree that the damage from the short-wavelength light to the substrate can be prevented. The transmittance of the short-wavelength light through the light-cutting layer is preferably 10% or less, and more preferably 5% or less, although the optical transmittance as high as approximately 50% may be allowed in some cases where the short-wavelength light has a specific wavelength and the substrate is formed of a specific material.

(v) Either of the light-cutting layer and the thermal-buffer layer can be arranged to have a function of a gas barrier.

(vi) The process according to the first aspect of the present invention can preferably include a substep (A-1) of forming a gas-barrier layer on at least one of the bottom surface and the upper surface of the substrate.

(vii) In the step (D), it is preferable that the non-monocrystalline film to be annealed be formed in the pattern by printing.

(viii) The short-wavelength light is preferably pulsed laser light, and more preferably excimer laser light.

(II) In order to accomplish the second object, the second aspect of the present invention is provided. According to the second aspect of the present invention, there is provided a thin-film device. The thin-film device is produced by the process according to the first aspect of the present invention, and comprises an inorganic film formed in a pattern over the substrate, where the substrate contains the resin material as the main component.

Preferably, the thin-film device according to the second aspect of the present invention may also have one or any possible combination of the following additional features (ix) to (xi).

(ix) The inorganic film may be a semiconductor film, and the semiconductor film preferably contains silicon as a main component. Preferable examples of the thin-film device having such a semiconductor film are semiconductor devices and solar cells which contain an active layer realized by the semiconductor film.

(x) The inorganic film may be a conductive inorganic film. A preferable example of the thin-film device having such a conductive inorganic film is a wired substrate, and another preferable example of the thin-film device having such a conductive inorganic film is a solar cell comprising either a wire or an electrode which is realized by the conductive inorganic film.

(xi) Other preferable examples of the thin-film device are a semiconductor device and a solar cell each comprising: a wire or an electrode which is realized by a conductive inorganic film; and an active layer realized by a semiconductor film; where each of the conductive inorganic film and the semiconductor film is part of the inorganic film.

(III) In order to accomplish the third object, the third aspect of the present invention is provided. According to the third aspect of the present invention, there is provided an electro-optic device comprising the thin-film device according to the second aspect of the present invention.

In addition, in order to accomplish the fourth object, the fourth aspect of the present invention is provided. According to the fourth aspect of the present invention, there is provided an thin-film sensor comprising the thin-film device according to the second aspect of the present invention.

(IV) The advantages of the present invention are described below.

In the process for producing a thin-film device according to the present invention, before the non-monocrystalline film which is to be annealed is formed in the pattern over the substrate containing the resin material as the main component, the light-cutting layer is formed over at least a region of the substrate over which the non-monocrystalline film to be annealed is not to be formed, and the light-cutting layer prevents damage from the short-wavelength light to the substrate by reducing the proportion of the short-wavelength light which reaches the substrate. Therefore, it is possible to anneal the non-monocrystalline film by the direct imaging technique so as to form the inorganic film having satisfactory quality without the damage from the short-wavelength light to the substrate (which has low thermal resistivity).

In addition, the process for producing a thin-film device according to the present invention enables annealing of non-monocrystalline films formed of various materials by use of the short-wavelength light having an identical wavelength, while suppressing damage to the substrate. That is, the process according to the present invention enables annealing of non-monocrystalline films formed of various materials.

Further, when the process according to the present invention is used, thin-film devices (such as semiconductor devices or wired substrates) which comprise an inorganic film having satisfactory quality and have superior element characteristics can be relatively easily produced by the direct imaging technique at low cost.

### DESCRIPTION OF THE DRAWINGS

FIG. 1 is a schematic cross-sectional view of the structure of a wired substrate as a thin-film device according to a first embodiment of the present invention.

FIGS. 2A, 2B, 2C, 2D, 2E, and 2F are cross-sectional views of the structures in representative steps in a process for producing the thin-film device of FIG. 1.

FIG. 3 is a graph indicating the wavelength dependence of the optical transmittance of a PET (polyethylene terephthalate) substrate.

FIG. 4 is a graph indicating the wavelength dependence of the optical transmittance of a SiNₓ film (having the thickness of 89 nm).

FIG. 5 is a graph indicating the wavelength dependence of the optical transmittance of a TiO₂ film (having the thickness of 210 nm).

FIG. 6 is a schematic cross-sectional view of the structure of a semiconductor device as a thin-film device according to a second embodiment of the present invention.

FIGS. 7A, 7B, 7C, 7D, 7E, 7F, and 7G are cross-sectional views of the structures in representative steps in a process for producing the thin-film device of FIG. 6 and an active-matrix substrate having the thin-film device of FIG. 6.

FIG. 8 is a schematic cross-sectional view of the structure of a solar cell as a thin-film device according to a third embodiment of the present invention.

FIG. 9 is a schematic cross-sectional view of the structure of a thin-film sensor according to a fourth embodiment of the present invention.

FIG. 10 is an exploded perspective view of the structure of an electro-optic device according to a fifth embodiment of the present invention.

### DESCRIPTION OF PREFERRED EMBODIMENTS

### 1. Thin-Film Device (First Embodiment)

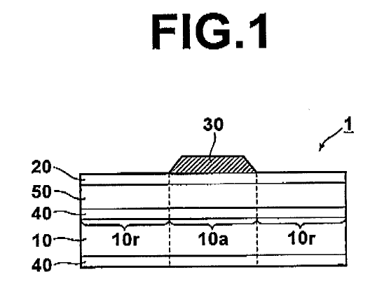

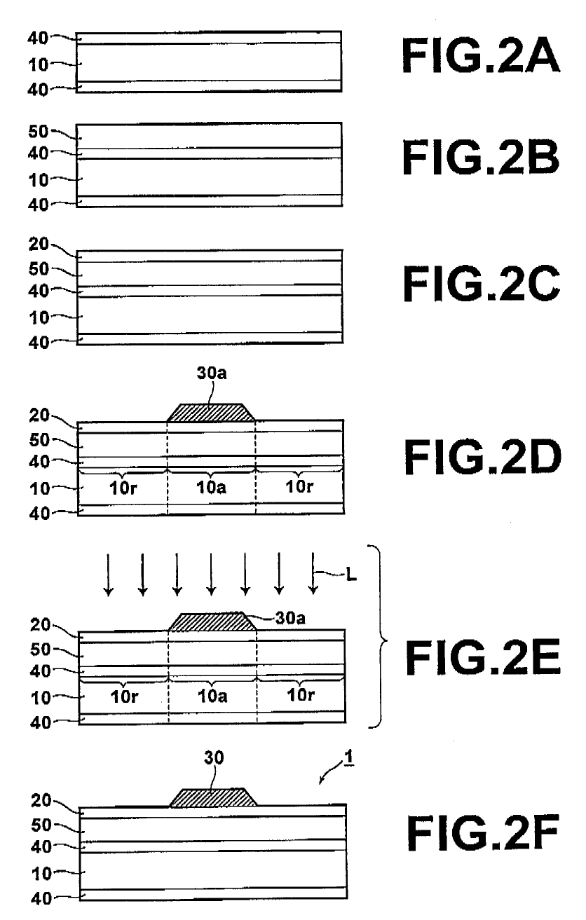

A thin-film device according to the first embodiment of the present invention and a process for producing the thin-film device according to the first embodiment are explained below with reference to FIGS. 1, 2A, 2B, 2C, 2D, 2E, and 2F. The thin-film device according to the first embodiment is a wired substrate. FIG. 1 shows a cross section, along the thickness direction, of the wired substrate 1 as the thin-film device according to the first embodiment, and FIGS. 2A, 2B, 2C, 2D, 2E, and 2F are cross-sectional views of the structures in representative steps in the process for producing the thin-film device of FIG. 1. In FIGS. 1, 2A, 2B, 2C, 2D, 2E, and 2F, the respective elements are illustrated schematically, and the dimensions of the illustrated elements are differentiated from the dimensions of the corresponding elements in the actual system for clarification.

As illustrated in FIG. 1, in the thin-film device (wired substrate) 1 according to the first embodiment, a thermal-buffer layer 50, a light-cutting layer 20, and an inorganic crystalline film 30 are formed in this order over a substrate 10. The substrate 10 contains a resin material as a main component, and gas-barrier layers 40 are arranged on the bottom surface and the upper surface of the substrate 10. The inorganic crystalline film 30 is formed, in a pattern, of one or more inorganic materials containing a metal element, although the inorganic crystalline film 30 may contain inevitable impurities. In the process for producing the thin-film device 1, the inorganic crystalline film 30 is obtained by forming a non-monocrystalline film 30a to be annealed, in the pattern by the direct imaging technique, and crystallizing the non-monocrystalline film by annealing, where the annealing is realized by irradiating the non-monocrystalline film 30a with short-wavelength light L.

Hereinbelow, the process for producing the thin-film device (wired substrate) 1 is explained in detail below with reference to FIGS. 2A, 2B, 2C, 2D, 2E, and 2F.

In the step (A), the substrate 10 is prepared as illustrated in FIG. 2A, where the gas-barrier layers 40 are arranged on the bottom and upper surfaces of the substrate 10. Specifically, the step (A) includes a substep (A-1) of forming the gas-barrier layers 40 on the bottom and upper surfaces of the substrate 10. The material of the substrate 10 is not specifically limited as long as the substrate 10 is a flexible substrate containing a resin material as a main component. For example, the substrate 10 may be formed of a resin of polyethylene terephthalate (PET), polyethylene naphthalate (PEN), polyimide (PI), or the like. It is preferable that the substrate 10 have superior thermal resistivity.

The gas-barrier layers 40 is provided for suppressing adverse influences, on the characteristics of the thin-film device 1, of oxygen, water, and the like which exist in the atmosphere and invade into the thin-film device 1 through the substrate 10 (which is permeable to gas). Generally, the gas-barrier layers 40 are required to have a water-vapor permeability coefficient of approximately 1×10⁻³ to 1×10⁻² g/m²/day, although the permeability coefficient of the gas-barrier layers 40 depends on the material properties and thickness of the gas-barrier layers 40. Each of the gas-barrier layers 40 may be constituted by a plurality of sublayers.

In the case where the gas-barrier layers are required to be thick, and tend to be colored by irradiation with short-wavelength light L, the characteristics of the thin-film device 1 can be adversely affected by irradiation with short-wavelength light L. Therefore, conventionally, it has been considered preferable that the gas-barrier layers be as resistant to absorption of the short-wavelength light L as possible. The SiNₓ films, the SiO₂ films, and the like are examples of the gas-barrier layers resistant to absorption of the short-wavelength light L. The properties of the SiNₓ films vary with the composition (i.e., the value of x), and the composition varies with the film-formation condition. Thus, conventionally, it has also been considered preferable that the gas-barrier layers have such a composition as to maximize the resistance to absorption of the short-wavelength light L, and be formed under such a film-formation condition as to realize satisfactory gas-barrier characteristics.

The above gas-barrier layers can also be used as the gas-barrier layers 40 in the thin-film device (wired substrate) 1 according to the first embodiment. However, in the thin-film device 1, the light-cutting layer 20 is formed above the gas-barrier layers 40 (in the step (C) as explained later), and the reduces the proportion of the short-wavelength light L which reaches the gas-barrier layers 40. Since the proportion of the short-wavelength light L which reaches the gas-barrier layers 40 is reduced by the light-cutting layer 20, no requirement is imposed on the absorption characteristics of the short-wavelength light L in the gas-barrier layers 40 as long as the gas-barrier layers 40 have a sufficient gas-barrier function.

The manner of formation of the gas-barrier layers 40 is not specifically limited. For example, the gas-barrier layers 40 may be formed by sputtering, PVD (physical vapor deposition), evaporation, or the like.

Next, in the step (B), the thermal-buffer layer 50 is formed over the substrate 10 having the gas-barrier layers 40 as illustrated in FIG. 2B. The thermal-buffer layer 50 is provided for preventing damage to the light-cutting layer 20 from the heat transferred from the light-cutting layer 20 (as explained later). Therefore, it is necessary that the thermal conductivity of the thermal-buffer layer 50 be low. The thermal-buffer layer 50 is, for example, a SiO₂ film. The thermal conductivity which the thermal-buffer layer 50 is required to have depends on the energy of the short-wavelength light L. The thermal conductivity of bulk SiO₂ is 2.8×10⁻³ cal/cm/sec/K. For example, JP11-102867A, paragraph No. 0040 reports that in the case where the short-wavelength light L is excimer laser light, the effect of thermally buffering the resin substrate sufficiently works when the thickness of the SiO₂ film is 1.0 to 2.0 micrometers. Therefore, in the case where the short-wavelength light L is excimer laser light, it is preferable that the gas-barrier layers 40 have a thermal conductivity equivalent to the thermal conductivity of the SiO₂ film having a thickness of 1.0 to 2.0 micrometers.

The manner of formation of the thermal-buffer layer 50 is not specifically limited. For example, the thermal-buffer layer 50 may be formed in a similar manner to the gas-barrier layers 40.

In the case where the thermal-buffer layer 50 also has a gas-barrier function, the thermal-buffer layer 50 may take on the function of a gas-barrier layer, or part of sublayers constituting a gas-barrier layer.

Subsequently, in the step (C), the light-cutting layer 20 is formed over the thermal-buffer layer 50 as illustrated in FIG. 2C. The light-cutting layer 20 is provided for reducing the proportion of the short-wavelength light L which reaches the substrate 10 so that the substrate 10 is not damaged by heat which is generated in the substrate 10 when the short-wavelength light L is absorbed in the regions 10r of the substrate 10 over which the non-monocrystalline film 30a to be annealed (and therefore the inorganic crystalline film 30) is not formed. The substrate 10 is damaged or not damaged according to the wavelength of the short-wavelength light L and the absorption characteristics of the short-wavelength light L.

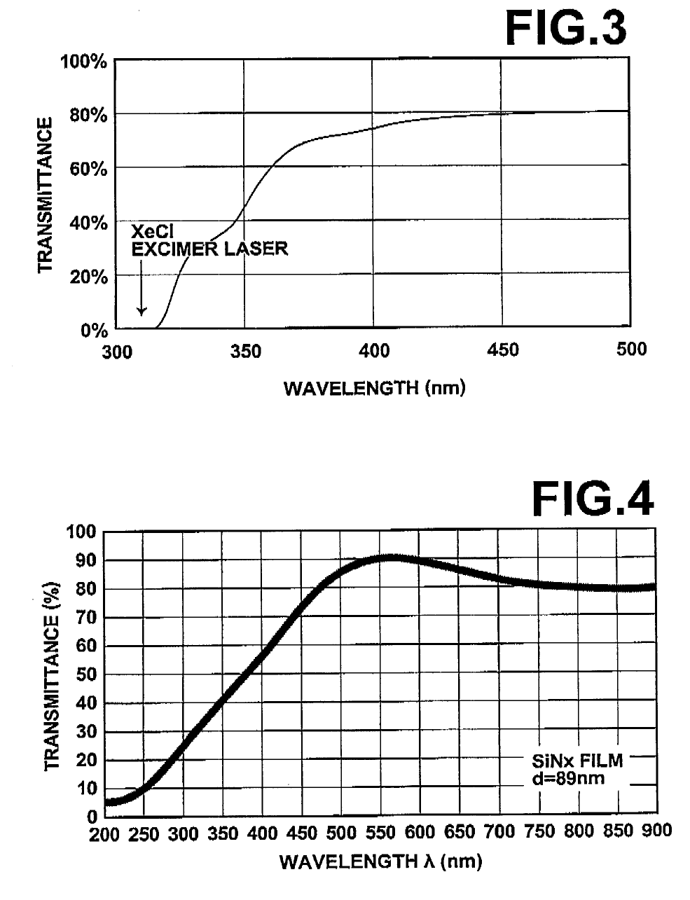

FIG. 3 shows the wavelength dependence of the optical transmittance of a PET (polyethylene terephthalate) substrate. As indicated in FIG. 3, the PET substrate absorbs approximately 100% of light at the wavelengths near the oscillation wavelength of XeCl excimer laser. The substrate 10 may be damaged even when the absorptance of the substrate 10 is approximately 15% in some cases where the energy of the short-wavelength light L is very high, and may not be damaged even when the absorptance of the substrate 10 is approximately 30% in other cases where the energy of the short-wavelength light L is relatively low. In consideration of the absorptances of the short-wavelength light L in major materials of which the resin-based substrate can be formed, the transmittance of the short-wavelength light L in the light-cutting layer 20 is preferably 10% or lower, and more preferably 5% or lower.

The light-cutting layer 20 is formed over the entire upper surface of the substrate 10 in the example illustrated in FIGS. 1, 2A, 2B, 2C, 2D, 2E, and 2F, and the purpose of the provision of the light-cutting layer 20 is to reduce the proportion of the short-wavelength light L which reaches the substrate 10 so as to prevent damage to the substrate 10 from the heat generated by absorption of the short-wavelength light L in the substrate 10. However, in the case where the non-monocrystalline film 30a to be annealed (which is to be formed in the aforementioned pattern in the step (E), which is explained later) per se has a function similar to the function of the light-cutting layer 20, there is no possibility that the regions 10a of the substrate 10 over which the non-monocrystalline film 30a is formed are damaged by the short-wavelength light L which passes through the non-monocrystalline film 30a. Therefore, in this case, it is sufficient that the light-cutting layer 20 be formed over only the regions 10r of the substrate 10 over which the non-monocrystalline film 30a (and therefore the inorganic crystalline film 30) is not to be formed.

For example, in the case where the absorptance of the short-wavelength light L in the non-monocrystalline film 30a to be annealed is high, the light-cutting layer 20 may not be formed over the regions 10a of the substrate 10 over which the non-monocrystalline film 30a is to be formed. On the other hand, in the case where the absorptance of the short-wavelength light L in the non-monocrystalline film 30a is not so high as in some oxide semiconductors, insulators, and the like, it is preferable that the light-cutting layer 20 be also formed over the regions 10a of the substrate 10 over which the non-monocrystalline film 30a is to be formed. In this case, it is possible to suppress damage to the substrate 10 by reducing the proportion of the short-wavelength light L which passes through the non-monocrystalline film 30a and reaches the substrate 10.

The manner of formation of the light-cutting layer 20 is not specifically limited. For example, the light-cutting layer 20 may be formed in a similar manner to the gas-barrier layers 40.

The material of the light-cutting layer 20 is not specifically limited as long as the light-cutting layer 20 can reduce the proportion of the short-wavelength light L (having the wavelength shorter than 350 nm) which reaches the substrate 10. The light-cutting layer 20 may be either a type which absorbs the short-wavelength light or a type which reflects the short-wavelength light.

In the case where the light-cutting layer 20 is the type which absorbs the short-wavelength light L, the light-cutting layer 20 may be formed of, for example, SiNₓ, SiO, SiNO, TiO₂, ZnS, or the like. As explained before for the gas-barrier layers 40, the properties of SiNₓ vary with the film-formation condition. It is preferable that the light-cutting layer 20 be formed so as to have a composition which realizes a property of sufficiently absorbing the short-wavelength light L.

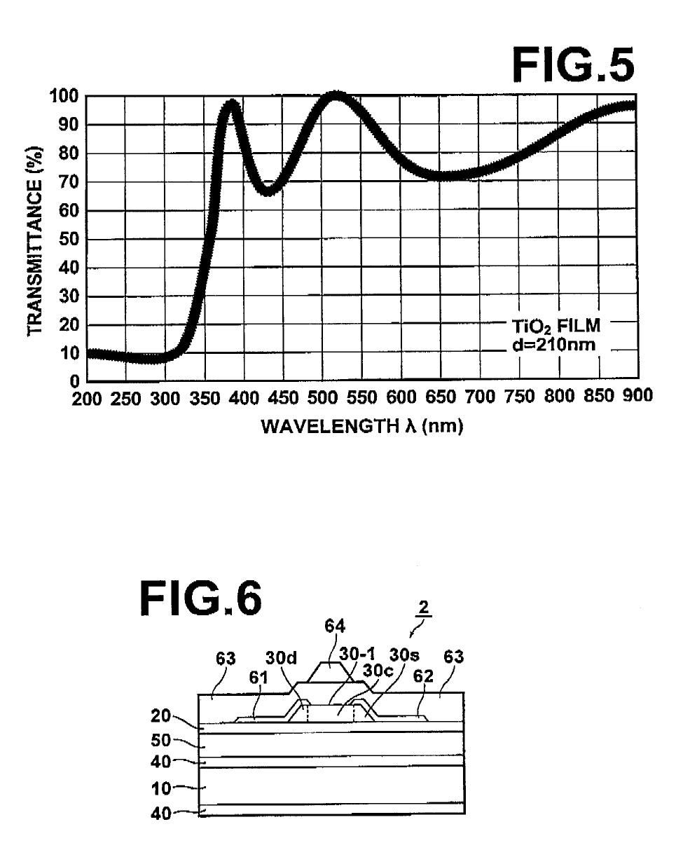

The thickness of the light-cutting layer 20 is determined according to the optical transmittance and the material properties of the light-cutting layer 20, where the required optical transmittance of the light-cutting layer 20 is determined based on the short-wavelength light L and the absorption characteristics of the substrate 10 as explained before. FIGS. 4 and 5 respectively show the wavelength dependences of the optical transmittances of a SiNₓ film and a TiO₂ film as the light-cutting layer 20.

Specifically, the SiNₓ film in FIG. 4 is formed by RF sputtering in the atmosphere of a mixture of Ar and 5.0 volume percent N₂ under the condition that the output power is 1 to 300 W and the vacuum degree is 0.67 Pa. The thickness of the SiNₓ film is 89 nm. The wavelength dependence of the optical transmittance of the SiNₓ film in FIG. 4 indicates that the transmittance of the short-wavelength light having a wavelength smaller than 350 nm through the SiNₓ film having the thickness of 89 nm (or greater) is approximately 40% or smaller.

In addition, the TiO₂ film in FIG. 5 is formed by RF sputtering in the atmosphere of a mixture of Ar and 1.0 volume percent O₂ under the condition that the output power is 400 W and the vacuum degree is 0.67 Pa. The thickness of the TiO₂ film is 210 nm. The wavelength dependence of the optical transmittance of the TiO₂ film in FIG. 5 indicates that the transmittance of the short-wavelength light having a wavelength smaller than 350 nm through the TiO₂ film having the thickness of 210 nm (or greater) is approximately 30% or smaller, and the transmittance of the short-wavelength light having a wavelength of 320 nm or smaller through the TiO₂ film having the thickness of 210 nm (or greater) is approximately 10% or smaller.

Therefore, it is possible to determine the material and the thickness of the light-cutting layer 20 according to a required transmittance of the light-cutting layer 20.

In the case where the light-cutting layer 20 is the type which reflects the short-wavelength light L, no specific limitation is imposed on the light-cutting layer 20 as long as the reflectance of the light-cutting layer 20 against the short-wavelength light L is sufficient. For example, the light-cutting layer 20 may be a metal film exhibiting a sufficient reflectance corresponding to a required transmittance.

In the case where the light-cutting layer 20 has a gas-barrier function, the light-cutting layer 20 may take on the function of a gas-barrier layer, or part of sublayers constituting a gas-barrier layer.

After the light-cutting layer 20 is formed as above, the non-monocrystalline film 30a to be annealed is formed in the aforementioned pattern on the light-cutting layer 20 (formed over the substrate 10) as illustrated in FIG. 2D in the step (D), and is then annealed by irradiating the non-monocrystalline film 30a with the short-wavelength light as illustrated in FIG. 2E in the step (E), so that the inorganic crystalline film 30 is formed.

Although the inorganic crystalline film 30 in the wired substrate 1 is not specifically limited as long as the inorganic crystalline film 30 is conductive, it is preferable that the inorganic crystalline film 30 be an arbitrary metal film, where the metal may be one or an alloy of Ag, Au, Cu, Pt, Pd, Ta, Nb, Mo, Ni, and Cr. Alternatively, the inorganic crystalline film 30 may be a conductive nonmetal film of, for example, carbon, ITO (indium tin oxide), or the like.

The inorganic crystalline film 30 can be produced by using the direct-imaging type liquid phase deposition. Although the manner of application of a raw-material solution containing the constituent material of the inorganic crystalline film 30 in the direct imaging is not specifically limited, use of a printing technique such as inkjet printing or screen printing is preferable.

Specifically, in the step (D), a raw-material solution of an organic solvent and a raw material which contains one or more metal elements constituting the inorganic crystalline film 30 is prepared, and the non-monocrystalline film 30a to be annealed is formed in the aforementioned pattern by liquid phase deposition, i.e., by applying the raw-material solution to the light-cutting layer 20 (formed over the substrate 10) as illustrated in FIG. 2D.

It is preferable to remove most of the organic solvent from the non-monocrystalline film 30a by room-temperature drying or the like, although the non-monocrystalline film 30a may be slightly heated to such a degree that the crystallization does not occur (e.g., to approximately 50° C.).

Although the raw-material solution for the wired substrate 1 is not specifically limited as long as satisfactory metal wiring is realized by baking, it is preferable to use a conductive paste of metal nanoparticles (which is hereinafter referred to as a metal nanopaste), since fine metal wiring having satisfactory electric conductivity can be realized by the use of the metal nanopaste. The metal nanopaste is a pastelike mixture in which metal nanoparticles are uniformly dispersed in a binder such as a thermosetting resin, where the metal nanoparticles have diameters on the order of several nanometers, and the surfaces of the metal nanoparticles are coated with a dispersing agent. When the metal nanopaste is baked, the dispersing agent covering the surfaces of the metal nanoparticles are removed by chemical reaction, and the metal nanoparticles are crystallized, so that the metal nanopaste is transformed into fine metal wiring having satisfactory electric conductivity.

Another example of the raw-material solution is a raw-material solution containing an organic solvent and an organic precursor material. An example of the organic precursor material is a metal alkoxide compound or the like (which can be used as a raw material in a sol-gel process). Alternatively, a raw-material solution containing an organic solvent and one or both of an inorganic material and an inorganic-organic complex precursor material may be used. An example of such a raw-material solution is a dispersion solution of inorganic particles and/or inorganic-organic complex particles, which is obtained by heating and stirring a liquid containing an organic solvent and an organic precursor material so as to produce particles of the organic precursor material in the liquid. (Such a technique of producing a dispersion solution of nanoparticles is hereinafter referred to as the nanoparticle method.) In the case where the nanoparticle method is used for producing the raw-material solution for the non-monocrystalline film 30a to be annealed, the amount of organic materials contained in the non-monocrystalline film 30a is reduced by the production of the particles before the film formation. In addition, the nanoparticles behave as crystal nuclei in crystal growth in the subsequent crystallization step, so that the crystal growth is facilitated. Therefore, it is preferable to use the nanoparticle method. In the case where the nanoparticle method is used, part of the organic precursor material may not be transformed into particles and may remain in the non-monocrystalline film 30a.

In the step (E), the non-monocrystalline film 30a to be annealed is crystallized so as to form the inorganic crystalline film 30 as illustrated in FIG. 2E. The crystallization is realized by laser annealing, which is performed by irradiating the non-monocrystalline film 30a with the short-wavelength light L. Since the laser annealing is a scanning type heating processing in which thermal rays (light) having high energy are used, the crystallization efficiency is high, and it is possible to control the energy which reaches the substrate, by changing the laser-irradiation condition including the scanning speed, the laser power, and the like. That is, in the laser annealing, the substrate is not directly heated, and the laser-irradiation condition can be adjusted according to the thermal resistivity of the substrate. Therefore, use of the laser annealing is preferable in the case where the low-thermal-resistance substrate such as the resin substrate is used.

Although the laser-light source used in the laser annealing is not specifically limited, a preferable example is the pulsed laser such as the excimer laser. The short-wavelength pulsed-laser light such as the excimer laser light is preferable, since great part of the energy of the short-wavelength pulsed-laser light is absorbed in a near-surface region, and it is easy to control the energy which reaches the substrate.

For example, in the case where an Ag paste (e.g., having the metal content of 30.8 weight percent, the average particle diameter of 3 to 7 nm, and the viscosity of 5 mPa·sec or lower) is used as the raw-material solution for the non-monocrystalline film 30a to be annealed, it is possible to realize Ag wiring having high electric conductivity, by laser annealing the non-monocrystalline film 30a with excimer laser at the wavelength of 248 nm so as to realize the irradiation power of 300 mJ/cm².

In the process according to the first embodiment, the non-monocrystalline film 30a to be annealed is formed in the pattern, so that the non-monocrystalline film 30a does not exist over the regions 10r of the substrate 10. However, the light-cutting layer 20 (reducing the proportion of the short-wavelength light L which reaches the substrate 10 and preventing damage from the short-wavelength light L to the substrate 10) is formed over at least the regions 10r of the substrate 10 (in the step (C)). Therefore, although the substrate 10 in the thin-film device (wired substrate) 1 according to the first embodiment is formed mainly of a resin material, and the thermal resistance of the substrate 10 is low, it is possible to anneal and crystallize the non-monocrystalline film 30a and satisfactorily form the inorganic crystalline film 30 without damaging the substrate 10, as illustrated in FIG. 2F. Thus, production of the thin-film device (wired substrate) 1 according to the first embodiment is completed.

The advantages of the process for producing a thin-film device (wired substrate) according to the first embodiment are summarized below.

(1) Since the light-cutting layer 20 (reducing the proportion of the short-wavelength light L which reaches the substrate 10 and preventing damage from the short-wavelength light L to the substrate 10) is formed over at least the regions 10r of the substrate 10 before the non-monocrystalline film 30a to be annealed is formed in the pattern on the substrate 10, it is possible to form the non-monocrystalline film 30a by using the direct imaging technique, and thereafter anneal the non-monocrystalline film 30a so as to satisfactorily form the inorganic crystalline film 30 without damaging the substrate 10.

(2) Since the non-monocrystalline film 30a can be crystallized while suppressing damage to the substrate 10 without changing the wavelength of the light used in the annealing, the process according to the first embodiment enables annealing of the non-monocrystalline film 30a even when the non-monocrystalline film 30a is formed of various materials.

(3) According to the process according to the first embodiment, it is possible to easily produce a thin-film device (wired substrate) 1 having a high-quality inorganic film and exhibiting superior characteristics, at low cost by using the direct imaging technique.

### 2. Thin-Film Device (Second Embodiment)

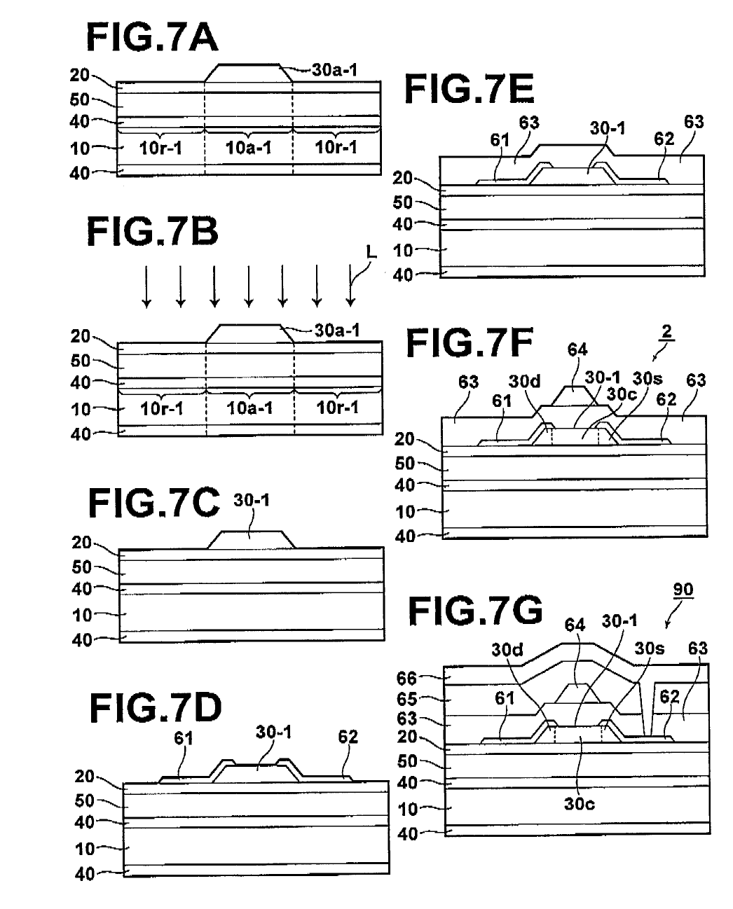

The thin-film device according to the second embodiment, an active-matrix substrate having the thin-film device as a pixel-switch element, and the process for producing the thin-film device and the active-matrix substrate according to the second embodiment are explained below with reference to FIGS. 6, 7A, 7B, 7C, 7D, 7E, 7F, and 7G. The thin-film device according to the second embodiment is a semiconductor device (specifically, a thin-film transistor (TFT)). In the following explanations, the thin-film transistor is assumed to be a top-gate type. However, the present invention can also be applied to the bottom-gate type thin-film transistor. FIG. 6 shows a cross section, along the thickness direction, of the semiconductor device 2 as the thin-film device according to the second embodiment, and FIGS. 7A, 7B, 7C, 7D, 7E, 7F, and 7G are cross-sectional views of the structures in representative steps in the process for producing the thin-film device 2 of FIG. 6 and the active-matrix substrate. In FIGS. 6, 7A, 7B, 7C, 7D, 7E, 7F, and 7G, the respective elements are illustrated schematically, and the dimensions of the illustrated elements are differentiated from the dimensions of the corresponding elements in the actual system for clarification.

As illustrated in FIG. 6, the semiconductor device (thin-film device) 2 according to the second embodiment is constituted by a substrate 10, a thermal-buffer layer 50, a light-cutting layer 20, an active layer 30-1, a gate-insulation film 63, and electrodes 61, 62, and 64. The substrate 10 contains a resin material as a main component, and the gas-barrier layers 40 are arranged on the bottom surface and the upper surface of the substrate 10. The active layer 30-1 is an inorganic crystalline film of an inorganic material containing one or more metal elements and/or one or more semiconductor elements, although the inorganic crystalline film 30-1 may contain inevitable impurities. The active layer 30-1 is formed in a pattern over the substrate 10 through the thermal-buffer layer 50 and the light-cutting layer 20.

The inorganic crystalline film 30-1 as the active layer is, for example, a metal-oxide film or a semiconductor film. Specifically, the inorganic crystalline film 30-1 is preferably a metal-oxide film containing one or more of the metal elements In, Ga, Zn, Sn, and Ti and having a semiconductive property, or a semiconductor film of Si and/or Ge, and particularly preferably a semiconductor film of Si.

Although, as explained above, the inorganic crystalline film 30-1 in the thin-film device (semiconductor device) 2 according to the second embodiment is different in the composition from the inorganic crystalline film 30 in the thin-film device (wired substrate) 1 according to the first embodiment, the steps in the process for producing the semiconductor device 2 according to the second embodiment up to the formation of the inorganic crystalline film 30-1 are similar to the steps (A) to (E) in the process for producing the wired substrate 1 according to the first embodiment. In particular, the substrate 10, the gas-barrier layers 40, the thermal-buffer layer 50, and the light-cutting layer 20 in the semiconductor device 2 according to the second embodiment are similar to the corresponding layers in the wired substrate 1 according to the first embodiment in the materials preferable for the respective layers and the manners of formation of the respective layers. Therefore, only the part of the process beginning from the step of forming the non-monocrystalline film 30a-1 in the pattern (corresponding to the step (D) in the process according to the first embodiment) is indicated in FIGS. 7A, 7B, 7C, 7D, 7E, 7F, and 7G. Hereinbelow, the process for producing the semiconductor device 2 and the active-matrix substrate according to the second embodiment is explained with reference to FIGS. 7A, 7B, 7C, 7D, 7E, 7F, and 7G.

First, the thermal-buffer layer 50 and the light-cutting layer 20 are formed over the substrate 10 (containing a resin material as a main component, and having the gas-barrier layers 40 on the bottom surface and the upper surface) in similar manners to the steps (A) to (C) in the first embodiment illustrated in FIGS. 2A to 2C, and then the non-monocrystalline film 30a-1 is formed in the pattern over the substrate 10 and the light-cutting layer 20 by using a raw-material solution of an organic solvent and a raw material which contains one or more metal elements and/or one or more semiconductor elements constituting the inorganic crystalline film 30-1, as illustrated in FIG. 6A in a similar manner to the first embodiment.

Since the inorganic crystalline film 30-1 according to the second embodiment is different from the inorganic crystalline film 30 in the constituent elements, the metal nanopaste, which is preferable in the step (d) in the first embodiment, cannot be used as the raw-material solution in the process according to the second embodiment. However, an example of the raw-material solution which can be used in the second embodiment is a raw-material solution containing an organic solvent and an organic precursor material which contains one or more inorganic materials constituting the inorganic crystalline film 30-1. Another example of the raw-material solution which can be used in the second embodiment is a raw-material solution containing an organic solvent and one or both of an inorganic material and an inorganic-organic complex precursor material. In the case where the inorganic crystalline film 30-1 is a semiconductor film of silicon, it is preferable to use as the raw-material solution a dispersion solution of nanoparticles of silicon which is obtained by the aforementioned nanoparticle method or the like. The example of the organic precursor material mentioned before for the first embodiment can also be used in the second embodiment.

In the next step, the non-monocrystalline film 30a-1 is crystallized in a similar manner to the first embodiment as illustrated in FIG. 7B, so that the inorganic crystalline film 30-1 of an inorganic material containing the aforementioned one or more metal elements and/or one or more semiconductor elements (and inevitable impurities) is formed in the aforementioned pattern over the substrate 10 through the thermal-buffer layer 50 and the light-cutting layer 20 as illustrated in FIG. 7C.

For example, in the case where the inorganic crystalline film 30 is formed of silicon, it is possible to produce a thin film of silicon having satisfactory crystallinity by laser annealing the non-monocrystalline film 30a-1 with excimer laser having the wavelength of 308 nm and the irradiation power of 100 to 500 mJ/cm².

In the subsequent steps, the drain electrode 61 and the source electrode 62 are formed as illustrated in FIG. 7D, and thereafter the gate-insulation film 63 of SiO₂ or the like is formed as illustrated in FIG. 7E. Further, the gate electrode 64 of n⁺Si, Al, an Al alloy, Ti, or the like is formed as illustrated in FIG. 7F.

The manners of the formation of the drain electrode 61, the source electrode 62, and the gate electrode 64 are not specifically limited. However, these electrodes are formed with conductive, inorganic crystalline films similar to the wiring in the wired substrate 1 according to the first embodiment. Therefore, it is possible to form each of the drain electrode 61, the source electrode 62, and the gate electrode 64 by forming in a pattern a film which contains the constituent elements of each of the drain electrode 61, the source electrode 62, and the gate electrode 64 and is to be annealed, and thereafter annealing the film, in a similar manner to the formation of the wiring in the wired substrate 1 in the steps (D) and (E) in the process according to the first embodiment. In addition, various wires on the semiconductor device 2 can also be formed in similar manners to the wiring in the wired substrate 1 according to the first embodiment. That is, each of the electrodes and the wires can be produced by preparing a raw-material solution for the electrode or wire, and performing the operations similar to the steps (D) and (E) in the process according to the first embodiment. Alternatively, the electrodes and the wires may be produced by patterning using lithography or the like after film formation by CVD (chemical vapor deposition), sputtering, or the like.

Although the thickness of the gate-insulation film 63 is not specifically limited, a preferable example of the thickness is approximately 100 nm. In addition, one of the techniques mentioned before for the formation of the gas-barrier layers 40 in the first embodiment can be used in formation of the gate-insulation film 63.

After the formation of the gate electrode 64, a source region 30s and a drain region 30d in the inorganic crystalline film 30 are doped with a dopant of P, B, or the like by using the gate electrode 64 as a mask. Thus, the inorganic crystalline film 30 becomes the active layer, and the production of the thin-film transistor (TFT) 2 is completed, as illustrated in FIG. 7F. The region between the source region 30s and the drain region 30d in the inorganic crystalline film 30 becomes a channel region 30c. In the case where the inorganic crystalline film 30 is formed of silicon, a preferable example of the doped amount is approximately 3.9×10¹⁵ ions/cm².

The active-matrix substrate 90 according to the present embodiment can be produced by forming an array of structures in each of which the active layer 30-1 and the electrodes 61, 62, and 64 are formed as illustrated in FIG. 6, on the layers of the substrate 10, the gas-barrier layers 40, the thermal-buffer layer 50, and the light-cutting layer 20, and then forming an interlayer insulation film 65 (of SiO₂, SiN, or the like) and pixel electrodes 66 over the array of the above structures as illustrated in FIG. 7G. Each of the pixel electrodes 66 is electrically connected to the source electrode 62 in one of the above structures through a contact hole formed by etching (e.g., dry etching, wet etching, or the like).

During the production of the active-matrix substrate 90, wires of scanning lines and signal lines are formed. The gate electrodes 64 have the function of the scanning lines in some cases, or the scanning lines are arranged separately from the gate electrode 64 in other cases. In addition, the drain electrodes 61 have the function of the signal lines in some cases, or the signal lines are arranged separately from the drain electrodes 61 in other cases.

Since the steps in the process according to the second embodiment up to the crystallization of the non-monocrystalline film are similar to the corresponding steps in the process according to the first embodiment, the process according to the second embodiment and the thin-film device 2 produced by the process according to the second embodiment have similar advantages to the process according to the first embodiment and the thin-film device 1 produced by the process according to the first embodiment. According to the second embodiment, it is possible to easily produce a thin-film device (semiconductor device) 2 having high crystallinity and superior element characteristics, at low cost by using the direct imaging technique.

Since the active-matrix substrate 90 uses the semiconductor device 2 having the superior element characteristics, the active-matrix substrate 90 exhibits high performance.

### 3. Thin-Film Device (Third Embodiment)

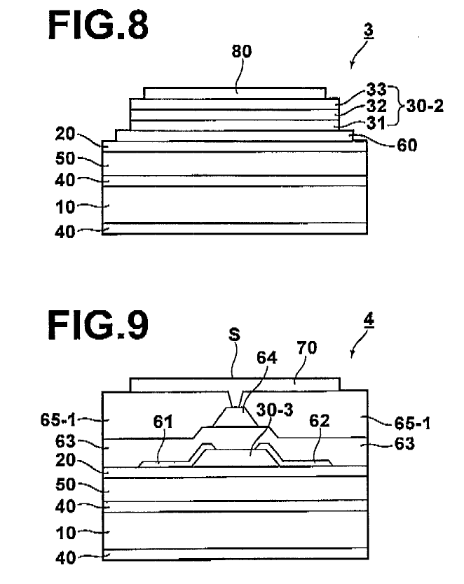

The thin-film device according to the third embodiment and the process for producing the thin-film device according to the third embodiment are explained below with reference to FIG. 8. The thin-film device according to the third embodiment is a semiconductor device, and is specifically a solar cell. FIG. 8 shows a cross section, along the thickness direction, of the solar cell 3 as the thin-film device according to the third embodiment. In FIG, 8, the respective elements are illustrated schematically, and the dimensions of the illustrated elements are differentiated from the dimensions of the corresponding elements in the actual system for clarification.

As illustrated in FIG. 8, the solar cell (thin-film device) 3 according to the third embodiment is constituted by a substrate 10, a thermal-buffer layer 50, a light-cutting layer 20, an active layer 30-2, a lower electrode 60, and an upper electrode 80. The substrate 10 contains a resin material as a main component, and the gas-barrier layers 40 are arranged on the bottom surface and the upper surface of the substrate 10. The active layer 30-2 is an inorganic crystalline film of an inorganic material containing one or more metal elements and/or one or more semiconductor elements, although the inorganic crystalline film 30-2 may contain inevitable impurities. The active layer 30-2 is formed in a pattern over the substrate 10 through the thermal-buffer layer 50 and the light-cutting layer 20.

The inorganic crystalline film 30-2 as the active layer is a lamination of a plurality of sublayers each having different semiconductivity. In the following explanations, it is assumed that the inorganic crystalline film 30-2 has a three-layer structure (p-i-n structure) in which an n-type semiconductor film 31, an i-type semiconductor film 32, and a p-type semiconductor film 33 are laminated. However, the structure of the inorganic crystalline film 30-2 is not limited to the three-layer structure, and may be, for example, a two-layer structure.

Each of the electrodes 60 and 80 is a conductive inorganic film, and may be, for example, a translucent film of a metal oxide such as SnO, a metal film of Al, or the like.

Hereinbelow, the process for producing the solar cell 3 according to the third embodiment is explained with reference to FIG. 8.

First, the thermal-buffer layer 50 and the light-cutting layer 20 are formed over the substrate 10 (containing a resin material as a main component, and having the gas-barrier layers 40 on the bottom surface and the upper surface) in similar manners to the steps (A) to (C) in the first embodiment illustrated in FIGS. 2A to 2C. Then, the lower electrode 60 is formed on the light-cutting layer 20, and the non-monocrystalline film to be annealed is formed in the aforementioned pattern on the lower electrode 60 by using a raw-material solution of an organic solvent and a raw material which contains one or more metal elements and/or one or more semiconductor elements constituting the inorganic crystalline film 30-2 in a similar manner to the first embodiment.

Since the inorganic crystalline film 30-2 in the solar cell 3 according to the third embodiment is also a semiconductor film, the inorganic crystalline film 30-2 can be formed of materials similar to the materials mentioned before for the inorganic crystalline film 30-1 in the second embodiment. However, for use in the solar cell, it is preferable that the active layer 30-2 have sufficient absorptivity in the visible wavelength range. In particular, in order to produce the p-i-n structure, it is preferable that the active layer 30-2 be formed of silicon. In addition, the preferable examples of the raw-material solution mentioned before for the inorganic crystalline film 30-1 in the second embodiment can also be used for the active layer 30-2 in the third embodiment.

After the non-monocrystalline film to be annealed is formed as above, the non-monocrystalline film is crystallized in a similar manner to the non-monocrystalline film 30a in the first embodiment, and then the upper electrode 80 is formed on the active layer 30-2. Thus, the solar cell 3 according to the third embodiment is obtained. The three different types of semiconductor films 31, 32, and 33 each having different semiconductivity can be formed in either of the following first and second manners. In the first manner, three different films which constitute the non-monocrystalline film, respectively correspond to the three different types of semiconductor films 31, 32, and 33, and are to be annealed are formed by using different raw-material solutions for the three different types of semiconductor films 31, 32, and 33, and thereafter the three different films are crystallized In the second manner, the three different types of semiconductor films 31, 32, and 33 can be produced by doping after crystallization of the non-monocrystalline film.

The manners of formation of the lower electrode 60 and the upper electrode 80 are not specifically limited. However, since the lower electrode 60 and the upper electrode 80 are conductive, inorganic crystalline films, each of the lower electrode 60 and the upper electrode 80 can be formed by forming in a pattern a film which contains one or more constituent elements of the electrode and is to be annealed, and thereafter annealing the film in a similar manner to the electrodes in the second embodiment. In addition, various wires on the solar cell 3 can also be formed in similar manners. Alternatively, the electrodes and the wires may be produced by patterning using lithography or the like after film formation by CVD (chemical vapor deposition), sputtering, or the like.

Since the steps in the process for producing the solar cell (thin-film device) 3 according to the third embodiment up to the crystallization of the non-monocrystalline film are similar to the corresponding steps in the process according to the first embodiment, the process according to the third embodiment and the solar cell 3 produced by the process according to the third embodiment have similar advantages to the process according to the first embodiment and the thin-film device 1 produced by the process according to the first embodiment. According to the third embodiment, it is possible to easily produce a thin-film device (solar cell) 3 having high crystallinity and superior element characteristics, at low cost by using the direct imaging technique.

Although, in the third embodiment, the semiconductor film as the active layer is formed by forming the non-monocrystalline film to be annealed, in a pattern by the direct imaging technique, and annealing the non-monocrystalline film by irradiation with the short-wavelength light L, alternatively, it is possible to form the semiconductor film in another manner, and form each of the electrodes and the wires by forming, in a pattern by the direct imaging technique, a non-monocrystalline film which corresponds to the electrode or wire and is to be annealed, and annealing the non-monocrystalline film by irradiation with the short-wavelength light L.

### 4. Thin-Film Sensor (Fourth Embodiment)

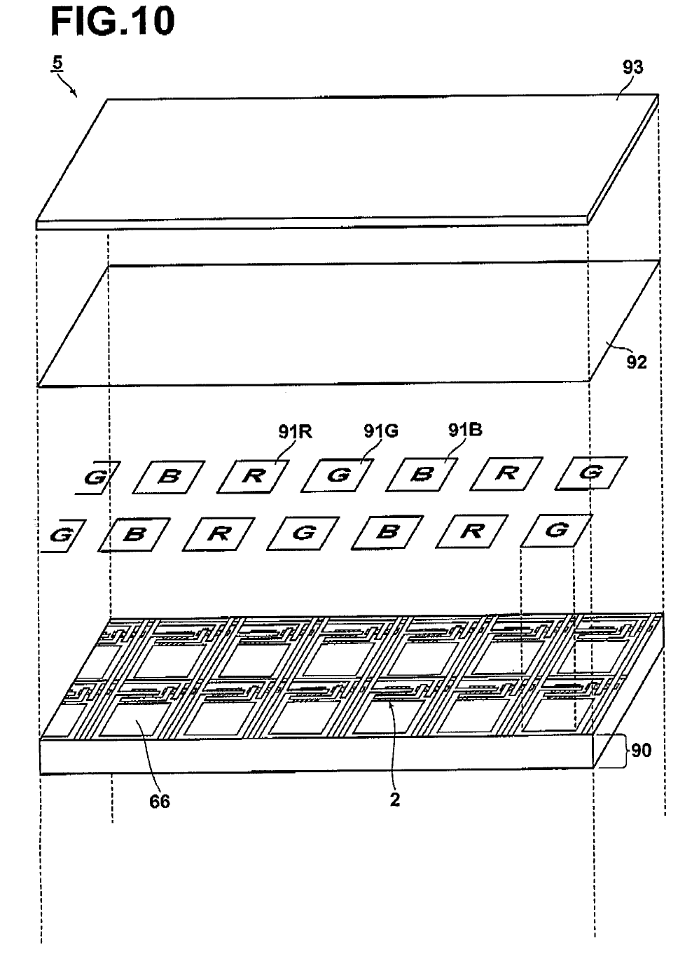

The thin-film sensor according to the fourth embodiment is explained below with reference to FIG. 9, which shows a cross section, along the thickness direction, of the thin-film sensor 4 according to the fourth embodiment of the present invention.

As illustrated in FIG. 9, the thin-film sensor 4 according to the fourth embodiment is constituted by the top-gate type semiconductor device 2 (of FIG. 6) according to the second embodiment, an interlayer insulation film 65-1 (of SiO₂, SiN, or the like) formed on the semiconductor device 2, and a sensing element 70 arranged over the interlayer insulation film 65-1 and connected to the gate electrode 64 through a contact hole formed through the interlayer insulation film 65-1. The sensing element 70 is a metal layer, and has an exposed surface as a sensing surface S. It is preferable that the sensing surface S be surface modified so that the sensing surface S can be combined with a material R to be sensed. The surface modification is chosen according to the use of the thin-film sensor 4. For example, the surface modification is a receptor such as an antibody in the case where the thin-film sensor 4 is used as a protein sensor, or a probe DNA in the case where the thin-film sensor 4 is used as a DNA chip. The interlayer insulation film 65-1 and the contact hole in the thin-film sensor 4 according to the fourth embodiment can be formed in similar manners to the interlayer insulation film 65 and the contact hole in the active-matrix substrate 90 according to the second embodiment.

When the material R to be sensed is combined with the sensing surface S, the potential profile at the sensing surface S changes, so that a potential difference occurs between before and after the combining. Therefore, the material R to be sensed can be sensed by detecting the potential difference by use of the semiconductor device 2.

Since the thin-film sensor 4 according to the fourth embodiment is constructed by using the semiconductor device 2 according to the second embodiment, and the semiconductor device 2 is superior in the element characteristics, the thin-film sensor 4 is also superior in the element characteristics, and has satisfactory sensitivity.

### 5. Electro-Optic Device (Fifth Embodiment)

Hereinbelow, the structure of an electro-optic device according to the fifth embodiment of the present invention is explained. The present invention can be applied to organic electroluminescence (EL) devices, liquid crystal devices, and the like. In the fifth embodiment, the present invention is applied to an organic EL device as an example of the electro-optic device according to the present invention. FIG. 10 is an exploded perspective view of the organic EL device according to the fifth embodiment.

As illustrated in FIG. 10, the organic EL device 5 according to the present embodiment is produced by forming light-emission layers 91R, 91G, and 91B in predetermined patterns on the active-matrix substrate 90 according to the second embodiment, and thereafter forming a common electrode 92 and a sealing film 93 in this order over the light-emission layers 91R, 91G, and 91B. The light-emission layers 91R, 91G, and 91B respectively emit red light (R), green light (G), and blue light (B) when electric current is applied to the light-emission layers 91R, 91G, and 91B.

Alternatively, the organic EL device 5 may be sealed by using another type of sealing member such as a metal can or a glass substrate, instead of the use of the sealing film 93. In this case, a drying agent such as calcium oxide may be contained in the sealed structure of the organic EL device 5.

The predetermined patterns in which the light-emission layers 91R, 91G, and 91B are formed correspond to pixel electrodes 66 so that each pixel is constituted by three dots respectively emitting red light, green light, and blue light. The common electrode 92 and the sealing film 93 are formed over the substantially entire upper surface of the active-matrix substrate 90.

In the organic EL device 5, the polarity of the pixel electrodes 66 is opposite to the polarity of the common electrode 92. That is, the pixel electrodes 66 are cathodes when the common electrode 92 is an anode, and the pixel electrodes 66 are anodes when the common electrode 92 is a cathode. The light-emission layers 91R, 91G, and 91B emit light when positive holes injected from an anode and electrons injected from a cathode recombine and the recombination energy is released.

In order to increase the emission efficiency, it is possible to arrange a positive-hole injection layer and/or a positive-hole transportation layer between the anode(s) and the light-emission layers 91R, 91G, and 91B. In addition, in order to increase the emission efficiency, it is also possible to arrange an electron injection layer and/or an electron transportation layer between the cathode(s) and the light-emission layers 91R, 91G, and 91B.

Since the electro-optic device (organic EL device) 5 according to the present embodiment is constructed by using the active-matrix substrate 90 according to the second embodiment explained before, the TFTs 2 constituting the electro-optic device according to the present embodiment are superior in the element uniformity. Therefore, the electro-optic device is greatly superior in the uniformity in the electro-optic characteristics such as the display quality. In addition, since each TFT 2 constituting the organic EL device 5 is superior in the element characteristics, the organic EL device 5 according to the present embodiment is superior to the conventional organic EL devices in reduction in the power consumption and the area on which peripheral circuits are formed, and in high freedom of choice of the types of peripheral circuits.

### 6. Variations

Although the thin-film devices according to the first, second, and third embodiments are respectively a wired substrate, a semiconductor device, and a solar cell, the thin-film device according to the present invention is not limited to the above embodiments.

In addition, the non-monocrystalline films to be annealed in the first, second, and third embodiments are crystallized by irradiation with the short-wavelength light, the non-monocrystalline films may be annealed in other manners.

### 7. Industrial Usability

The process for producing a thin-film device according to the present invention can be preferably used in manufacture, by use of the direct imaging technique, of semiconductor devices such as wired substrates, solar cells, thin-film transistors (TFTs), and other devices similar to the semiconductor devices.

What is claimed is:

1. A process for producing a thin-film device, comprising the steps of:
(A) preparing a substrate which contains a resin material as a main component;
(B) forming a thermal-buffer layer over said substrate;
(C) forming a light-cutting layer over at least a region of the substrate over which a non-monocrystalline film to be annealed is not to be formed, where the light-cutting layer has a function of preventing damage from short-wavelength light to the substrate by reducing a proportion of the short-wavelength light which reaches the substrate when the non-monocrystalline film is irradiated with the short-wavelength light;
(D) forming said non-monocrystalline film in a pattern over said substrate having said thermal-buffer layer, and
(E) forming an inorganic film by irradiating said non-monocrystalline film with said short-wavelength light so as to anneal the non-monocrystalline film.

2. A process according to claim 1, wherein said step (D) and said step (E) are performed one or more times after the step (E) is first performed.

3. A process according to claim 1, wherein said inorganic film has crystallinity.

4. A process according to claim 1, wherein said light-cutting layer absorbs said short-wavelength light.

5. A process according to claim 1, wherein said light-cutting layer reflects said short-wavelength light.

6. A process according to claim 1, wherein the transmittance of said short-wavelength light through said light-cutting layer is 10% or less.

7. A process according to claim 6, wherein the transmittance of said short-wavelength light through said light-cutting layer is 5% or less.

8. A process according to claim 1, wherein at least one of said light-cutting layer and said thermal-buffer layer has a function of a gas barrier.

9. A process according to claim 1, wherein said step (A) includes a substep (A-1) of forming a gas-barrier layer on at least one of a bottom surface and an upper surface of said substrate.

10. A process according to claim 1, wherein in said step (D), said non-monocrystalline film is formed in said pattern by printing.

11. A process according to claim 1, wherein said short-wavelength light is pulsed laser light.

12. A process according to claim 11, wherein said short-wavelength light is excimer laser light.

13. A thin-film device which is produced by said process according to claim 1, and comprises said inorganic film formed in said pattern over said substrate, and the substrate contains said resin material as the main component.

14. A thin-film device according to claim 13, wherein said inorganic film is a semiconductor film.

15. A thin-film device according to claim 14, wherein said semiconductor film contains silicon as a main component.

16. A thin-film device according to claim 13, wherein said inorganic film is a conductive inorganic film.

17. A thin-film device according to claim 16, being a wired substrate.

18. A thin-film device according to claim 14, being a solar cell comprising an active layer realized by said semiconductor film.

19. A thin-film device according to claim 16, being a solar cell comprising at least one of a wire and an electrode which are realized by said conductive inorganic film.

20. A thin-film device according to claim 13, being a solar cell comprising:
at least one of a wire and an electrode which are realized by a conductive inorganic film; and
an active layer realized by a semiconductor film;
wherein each of said conductive inorganic film and said semiconductor film is part of said inorganic film.

21. A thin-film device according to claim 14, being a semiconductor device comprising an active layer realized by said semiconductor film.

22. A thin-film device according to claim 13, being a semiconductor device comprising:
at least one of a wire and an electrode which are realized by a conductive inorganic film; and
an active layer realized by a semiconductor film;
wherein each of said conductive inorganic film and said semiconductor film is part of said inorganic film.

23. An electro-optic device comprising the thin-film device according to claim 21.

24. An electro-optic device comprising the thin-film device according to claim 22.

25. A thin-film sensor comprising the thin-film device according to claim 21.

26. A thin-film sensor comprising the thin-film device according to claim 22.
